(19) United States
(12) Patent Application Publication
(10) Pub. No.: US 2025/0176188 A1
(43) Pub. Date: May 29, 2025

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventors: Hyo Sub YEOM, Gyeonggi-do (KR); Heung Yeul LEE, Gyeonggi-do (KR)

(21) Appl. No.: 18/608,931

(22) Filed: Mar. 19, 2024

(30) Foreign Application Priority Data
Nov. 23, 2023 (KR) 10-2023-0163905

(51) Int. Cl. H10B 43/40; H01L 23/528; H10B 41/10; H10B 41/27; H10B 41/40; H10B 43/10; H10B 43/27

(52) U.S. Cl. CPC H10B 43/40; H01L 23/5283; H10B 41/10; H10B 41/27; H10B 41/40; H10B 43/10; H10B 43/27

(57) ABSTRACT

A semiconductor device may include: a peripheral circuit; a gate structure disposed on the peripheral circuit and including stacked gate lines; a first recess staircase structure disposed within the gate structure; a second recess staircase structure disposed within the gate structure and adjacent to the first recess staircase structure in a first direction; a first gap-fill insulating layer including a first line portion formed within the first recess staircase structure, a second line portion formed within the second recess staircase structure, and a bridge portion connecting the first line portion and the second line portion to each other; and peripheral contact plugs extending into the gate structure through the bridge portion of the first gap-fill insulating layer and connected to the peripheral circuit.

### CROSS-REFERENCE TO RELATED APPLICATION

This application claims priority under 35 U.S.C. § 119 to Korean Patent Application No. 10-2023-0163905 filed on Nov. 23, 2023, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a peripheral circuit; a gate structure disposed on the peripheral circuit and including stacked gate lines; a first recess staircase structure disposed within the gate structure; a second recess staircase structure disposed within the gate structure and adjacent to the first recess staircase structure in a first direction; a first gap-fill insulating layer including a first line portion formed within the first recess staircase structure, a second line portion formed within the second recess staircase structure, and a bridge portion disposed between the first line portion and the second line portion and connecting the first line portion and the second line portion to each other; and peripheral contact plugs extending into the gate structure through the bridge portion of the first gap-fill insulating layer and connected to the peripheral circuit.

In an embodiment, a semiconductor device may include: a peripheral circuit; a gate structure disposed on the peripheral circuit and including stacked gate lines; a first recess staircase structure disposed within the gate structure; a second recess staircase structure disposed within the gate structure; a first gap-fill insulating layer including a first line portion formed within the first recess staircase structure, a second line portion formed within the second recess staircase structure, and bridge portions connecting the first line portion and the second line portion to each other; and a second gap-fill insulating layer located between the bridge portions and between the first line portion and the second line portion, wherein the second gap-fill insulating layer includes a void extending along an edge of the first gap-fill insulating layer.

In an embodiment, a manufacturing method of a semiconductor device may include: forming a stack including first material layers and second material layers that are alternately stacked; forming a hard mask pattern on the stack, the hard mask pattern including a first opening having a ladder shape; forming a first recess staircase structure by etching the stack exposed by the first opening; forming a second recess staircase structure by etching the stack exposed by the first opening; forming a first gap-fill insulating layer including a first line portion formed within the first recess staircase structure, a second line portion formed within the second recess staircase structure, and a bridge portion disposed between the first line portion and the second line portion and connecting the first line portion and the second line portion to each other; forming a second opening by removing the hard mask pattern; and forming a second gap-fill insulating layer in the second opening, the second gap-fill insulating layer including a void. By “ladder shape” as this term is used here, it is meant a structure having a series of horizontal and vertical elements resembling the steps of a ladder.

### BRIEF DESCRIPTION OF THE DRAWINGS

FIGS. 1A to 1E are diagrams illustrating the structure of a semiconductor device in accordance with an embodiment.

FIGS. 2A and 2B are diagrams for describing the structure of a semiconductor device in accordance with an embodiment.

FIGS. 3A, 4A, 5A, 6A, and 7A and FIGS. 3B, 4B, 5B, 6B, and 7B are diagrams for describing a manufacturing method of a semiconductor device in accordance with an embodiment.

FIGS. 8A to 8C are diagrams for describing a manufacturing method of a semiconductor device in accordance with an embodiment.

### DETAILED DESCRIPTION

Various embodiments are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the scope of the present disclosure will be described with reference to the accompanying drawings.

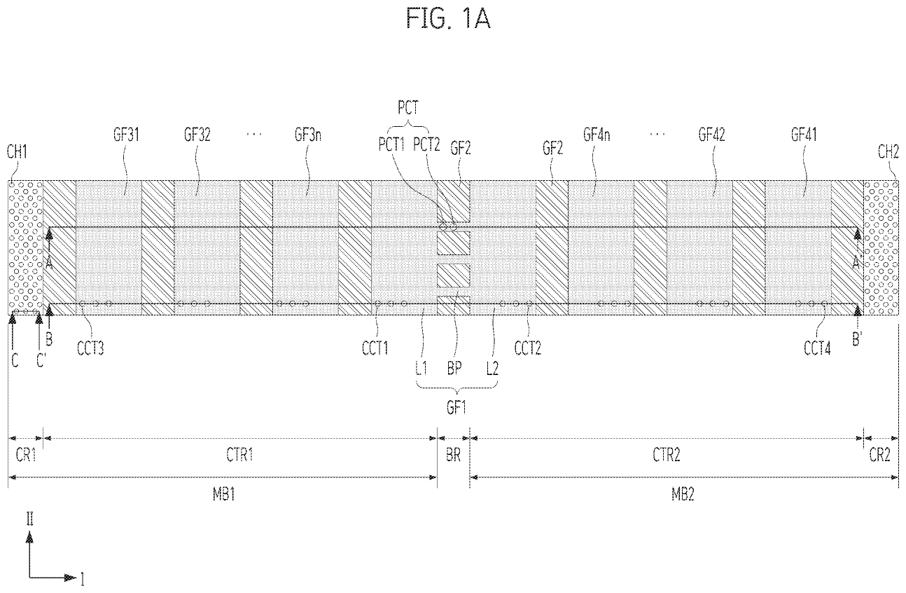

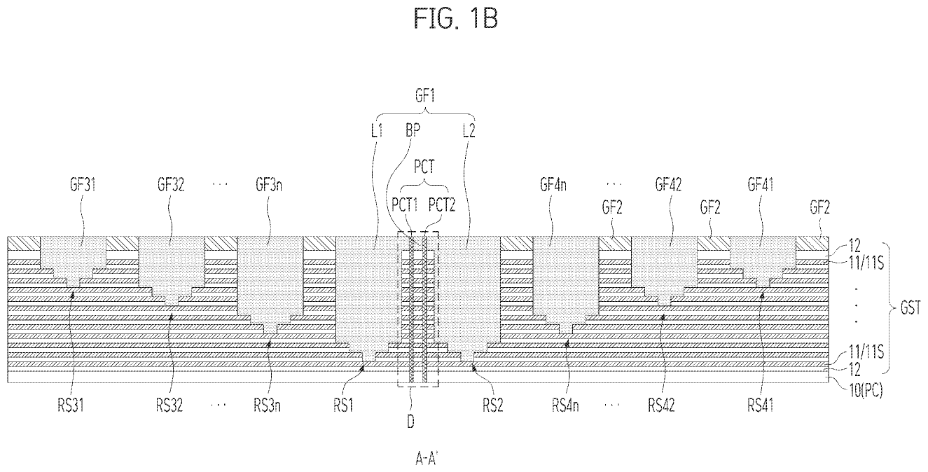

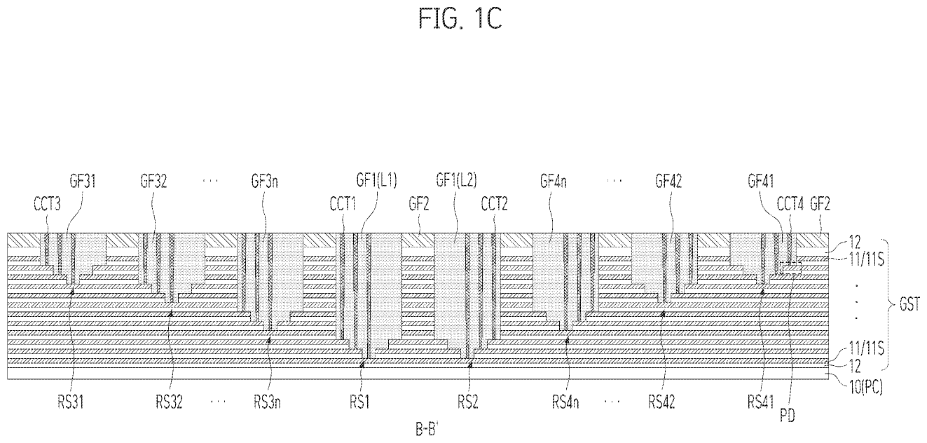

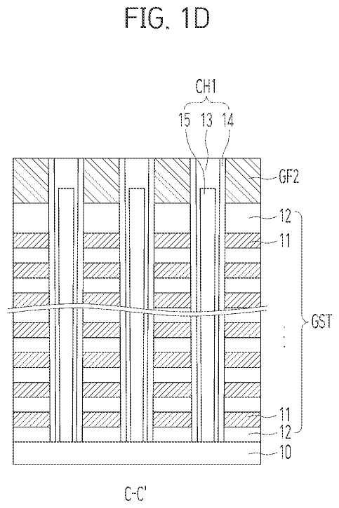

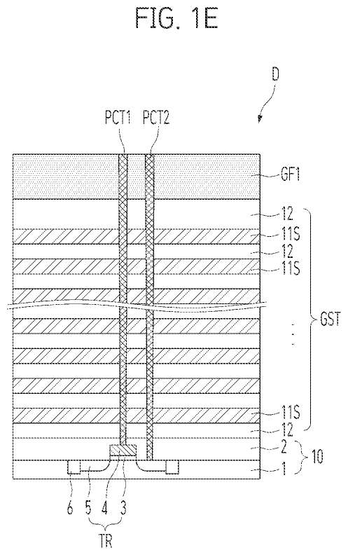

FIGS. 1A to 1E are diagrams illustrating the structure of a semiconductor device in accordance with an embodiment. FIG. 1A is a plan view illustrating a structure of a semiconductor device in accordance with an embodiment. FIG. 1B is a cross-sectional view taken along line A-A′ of FIG. 1A, FIG. 1C is a cross-sectional view taken along line B-B′ of FIG. 1A, FIG. 1D is a cross-sectional view taken along line C-C′ of FIG. 1A, and FIG. 1E is an enlarged view of region D in FIG. 1B.

Referring to FIGS. 1A to 1D, the semiconductor device may include a gate structure GST, a first recess staircase structure RS1, a second recess staircase structure RS2, and a first gap-fill insulating layer GF1. The semiconductor device may further include a lower structure 10, third recess staircase structures RS31 to RS3n, fourth recess staircase structures RS41 to RS4n, a second gap-fill insulating layer GF2, third gap-fill insulating layers GF31 to GF3n, fourth gap-fill insulating layers GF41 to GF4n, a peripheral contact plug PCT, and cell contact plugs CCT1 to CCT4. Here, n may be an integer of 1 or more.

The lower structure 10 may include a substrate 1, an interlayer insulating layer 2, a peripheral circuit PC, a source structure, an interconnection structure, and the like. An element isolation layer 6 may be located within the substrate 1, and an active region may be defined by the element isolation layer 6. The peripheral circuit PC may include a page buffer, a row decoder, a global data line (GDL) repeater, and the like. In an embodiment, the peripheral circuit PC may include a transistor TR. The transistor TR may be located in the active region, and may include a gate insulating layer 3, a gate electrode 4, and a junction 5. The transistor may constitute a repeater connected to the middle of a global data line.

The gate structure GST may be located on the lower structure 10. In an embodiment, the gate structure GST may be disposed on the peripheral circuit PC. The gate structure GST may include stacked gate lines 11. In an embodiment, the gate structure GST may include the gate lines 11 and insulating layers 12 that are alternately stacked. The gate lines 11 may be word lines, source select lines, or drain select lines. The insulating layers 12 are used to insulate the stacked gate lines 11 from each other, and may each include oxide, nitride, air gap, and the like.

The gate structure GST may include a first cell region CR1, a second cell region CR2, a first contact region CTR1, a second contact region CTR2, and a bridge region BR. The first cell region CR1 and the second cell region CR2 may be adjacent to each other in a first direction I. The bridge region BR may be located between the first cell region CR1 and the second cell region CR2. The first contact region CTR1 may be located between the first cell region CR1 and the bridge region BR, and the second contact region CTR2 may be located between the second cell region CR2 and the bridge region BR.

The first cell region CR1 and the second cell region CR2 may be regions where memory cells are stacked. The first contact region CTR1 and the second contact region CTR2 may be regions where an interconnection structure for transmitting a driving voltage to the stacked memory cells is located. The first cell region CR1 and the first contact region CTR1 may belong to a first memory block MB1, and the second cell region CR2 and the second contact region CTR2 may belong to a second memory block MB2. Here, a memory block may be a unit of an erase operation.

A first channel structure CH1 may extend through the first cell region CR1 of the gate structure GST. The first channel structure CH1 may include at least one of a channel layer 13, a memory layer 14, and an insulating core 15. The memory layer 14 may include at least one of a blocking layer, a data storage layer, and a tunneling layer. The data storage layer may include a floating gate, polysilicon, a charge trap material, nitride, a variable resistance material, or the like. A second channel structure CH2 may extend through the second cell region CR2 of the gate structure GST. The second channel structure CH2 may have a similar structure to the first channel structure CH1.

Recess staircase structures may be located in the first contact region CTR1 and the second contact region CTR2 of the gate structure GST. The recess staircase structures may be formed by pattering the gate structure GST in a staircase shape, and pads PD of the gate lines may be defined through the recess staircase structures. The pad PD is a portion of the gate line which is not covered by an upper gate line. The gate structure GST may include a plurality of recess staircase structures, and the recess staircase structures may be located at different levels. The pads PD of the gate lines 11 may be respectively defined by the recess staircase structures located at the different levels. The first recess staircase structure RS1 and the second recess staircase structure RS2 may be located within the gate structure GST. The first recess staircase structure RS1 and the second recess staircase structure RS2 may be located between the first channel structure CH1 and the second channel structure CH2. The first recess staircase structure RS1 may be located in the first contact region CTR1, and the second recess staircase structure RS2 may be located in the second contact region CTR2. The first recess staircase structure RS1 and the second recess staircase structure RS2 may be adjacent to each other in the first direction I with the bridge region BR interposed therebetween. The first recess staircase structure RS1 may belong to the first memory block MB1, and the second recess staircase structure RS2 may belong to the second memory block MB2.

The third recess staircase structures RS31 to RS3n and the fourth recess staircase structures RS41 to RS4n may be located within the gate structure GST. The third recess staircase structures RS31 to RS3n may be located between the first channel structure CH1 and the first recess staircase structure RS1. Pads of the gate lines 11 of the first memory block MB1 may be defined by the first recess staircase structure RS1 and the third recess staircase structures RS31 to RS3n, respectively. The fourth recess staircase structures RS41 to RS4n may be located between the second channel structure CH2 and the second recess staircase structure RS2. Pads of the gate lines 11 of the second memory block MB2 may be defined by the second recess staircase structure RS2 and the fourth recess staircase structures RS41 to RS4n, respectively.

The first gap-fill insulating layer GF1 may include a first line portion L1, a second line portion L2, and a bridge portion BP. For example, the first gap-fill insulating layer GF1 may include a plurality of bridge portions BP arranged in a second direction II intersecting the first direction I. The first line portion L1 may be located within the first recess staircase structure RS1, and the second line portion L2 may be located within the second recess staircase structure RS2. The bridge portion BP may be located in the bridge region BR, and may connect the first line portion L1 and the second line portion L2 to each other.

The first line portion L1 and the second line portion L2 may extend in the second direction II. The bridge portion BP may extend in the first direction I. In a plane defined by the first direction I and the second direction II (see FIG. 1A), the first gap-fill insulating layer GF1 may have a ladder shape. In a cross-sectional view (see FIG. 1B), the first line portion L1 and the second line portion L2 may extend into the gate structure GST, and may have bottom surfaces having a staircase shape. The bottom surface of the first line portion L1 and the bottom surface of the second line portion L2 may be located at the same level or different levels. The bridge portion BP may be located on the gate structure GST.

The second gap-fill insulating layers GF2 may be located on the gate structure GST, and may be located between the first and second line portions L1 and L2 and the pairs among the first, third, and fourth gap-fill insulating layers GF1, GF31 to GF3n, and GF41 to GF4n. The second gap-fill insulating layers GF2 may extend in the second direction II between the neighboring pairs among the third gap-fill insulating layers GF31 to GF3n and between the neighboring pairs among the fourth gap-fill insulating layers GF41 to GF4n. The second gap-fill insulating layers GF2 may have an island shape surrounded by the first line portion L1, the second line portion L2, and the bridge portion BP, and the second gap-fill insulating layers GF2 having the island shape may be spaced apart from each other in the second direction II.

The third gap-fill insulating layers GF31 to GF3n may be located within the third recess staircase structures RS31 to RS3n, respectively. The third gap-fill insulating layers GF31 to GF3n may have bottom surfaces having a staircase shape. The fourth gap-fill insulating layers GF41 to GF4n may be located within the fourth recess staircase structures RS41 to RS4n, respectively. The fourth gap-fill insulating layers GF41 to GF4n may have bottom surfaces having a staircase shape.

The cell contact plugs CCT1 to CCT4 may extend through the gap-fill insulating layers GF1, GF31 to GF3n, and GF41 to GF4n, and may be connected to the pads PD of the gate lines 11, respectively. First cell contact plugs CCT1 may extend through the first line portion L1 of the first gap-fill insulating layer GF1, and may be respectively connected to the pads PD defined through the first recess staircase structure RS1. Second cell contact plugs CCT2 may extend through the second line portion L2 of the first gap-fill insulating layer GF1, and may be respectively connected to the pads PD defined through the second recess staircase structure RS2. Third cell contact plugs CCT3 may extend through the third gap-fill insulating layers GF31 to GF3n, and may be respectively connected to the pads PD defined through the third recess staircase structures RS31 to RS3n. Fourth cell contact plugs CCT4 may extend through the fourth gap-fill insulating layers GF41 to GF4n, and may be respectively connected to the pads PD defined through the fourth recess staircase structures RS41 to RS4n.

The peripheral contact plugs PCT may extend through the gate structure GST, and may be electrically connected to the peripheral circuit PC. Between the first recess staircase structure RS1 and the second recess staircase structure RS2, the gate structure GST may include sacrificial layers 11S and insulating layers 12 that are alternately stacked. Here, the sacrificial layers 11S may be layers remaining without being replaced with the gate lines 11 in a manufacturing process. The peripheral contact plugs PCT may extend through the sacrificial layers 11S and the insulating layers 12 that are alternately stacked. Alternatively, the peripheral contact plugs PCT may extend through the gate lines 11 and the insulating layers 12, and insulating spacers may surround sidewalls of the peripheral contact plugs PCT.

The peripheral contact plugs PCT may include a first peripheral contact plug PCT1 and a second peripheral contact plug PCT2. The first peripheral contact plug PCT1 may be connected to the gate electrode 4 of the transistor TR. The second peripheral contact plug PCT2 may be connected to the junction 5 of the transistor TR. In an embodiment, the transistor TR may belong to the global data line repeater. The first and second peripheral contact plugs PCT1 and PCT2 may be directly connected to the transistor TR or be connected to the transistor TR through an interconnection structure. In an embodiment, the first and second peripheral contact plugs PCT1 and PCT2 may be connected to the transistor TR through a contact plug and/or a wiring line.

According to the structure described above, the first gap-fill insulating layer GF1 may have the ladder shape. The peripheral contact plugs PCT may be spaced apart from an edge of the bridge portion BP, and may extend into the gate structure GST through the bridge portion BP.

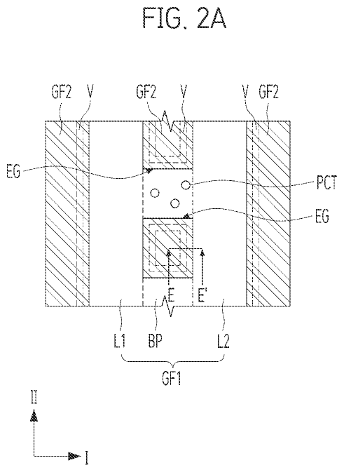

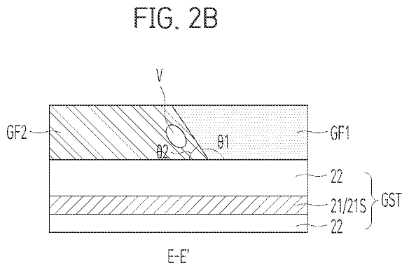

FIGS. 2A and 2B are diagrams for describing the structure of a semiconductor device in accordance with an embodiment. FIG. 2B is a cross-sectional view taken along line E-E′ of FIG. 2A. Hereinafter, the content overlapping with the previously described content may be omitted.

Referring to FIGS. 2A and 2B, the semiconductor device may include a gate structure GST, a first gap-fill insulating layer GF1, a second gap-fill insulating layer GF2, and peripheral contact plugs PCT. The gate structure GST may include gate lines 21 and insulating layers 22 that are alternately stacked or include sacrificial layers 21S and insulating layers 22 that are alternately stacked.

The first gap-fill insulating layer GF1 may include a first line portion L1, a second line portion L2, and a bridge portion BP. The second gap-fill insulating layer GF2 may be formed between the first line portion L1, the second line portion L2, and the bridge portion BP. The second gap-fill insulating layer GF2 may include a void therein. The void V may be located adjacent to an edge EG of the first gap-fill insulating layer GF1, but may be located so as not to be in contact with the edge EG. The void V may extend along the edge EG of the first gap-fill insulating layer GF1. The void V may be caused by a gradient of a sidewall of the first gap-fill insulating layer GF1 in a manufacturing process. In an embodiment, the first gap-fill insulating layer GF1 may have an inclined sidewall of an obtuse angle θ1, and the second gap-fill insulating layer GF2 may have an inclined sidewall of an acute angle θ2. When the second gap-fill insulating layer GF2 is formed by a deposition method, the void V may be formed within the second gap-fill insulating layer GF2 by the inclined sidewall of the first gap-fill insulating layer GF1. The void V may be spaced apart from the peripheral contact plugs PCT.

When the first gap-fill insulating layer GF1 does not include the bridge portion BP, the void V and the peripheral contact plugs PCT may overlap with each other, and a bridge between the peripheral contact plugs PCT may be caused through the void V. According to an embodiment of the present disclosure, the first gap-fill insulating layer GF1 may have a ladder shape in which it includes the bridge portion BP instead of a line shape in which it extends in the second direction II. By locating the bridge portion BP so as to correspond to the peripheral contact plugs PCT, the peripheral contact plugs PCT may be spaced apart from the void V, and the bridge caused through the void V may be prevented or reduced.

According to the structure described above, even though the second gap-fill insulating layer GF2 includes the void V, a location of the void V may be adjusted through the bridge portion BP. The void V might not exist within a region covered by the bridge portion BP, and the peripheral contact plugs PCT may be located in the bridge portion BP, such that the peripheral contact plugs PCT and the void V may be spaced apart from each other. Accordingly, it is possible to prevent or reduce the bridge caused between the peripheral contact plugs PCT through the void V. In an embodiment, it is possible to prevent or reduce a bridge caused between a peripheral contact plug PCT connected to a gate electrode of a transistor included in a global data line and a peripheral contact plug PCT connected to a junction of the transistor.

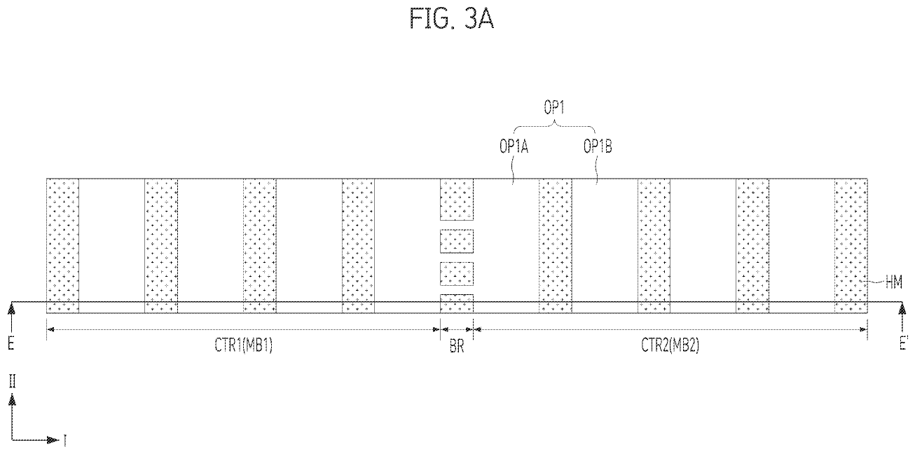

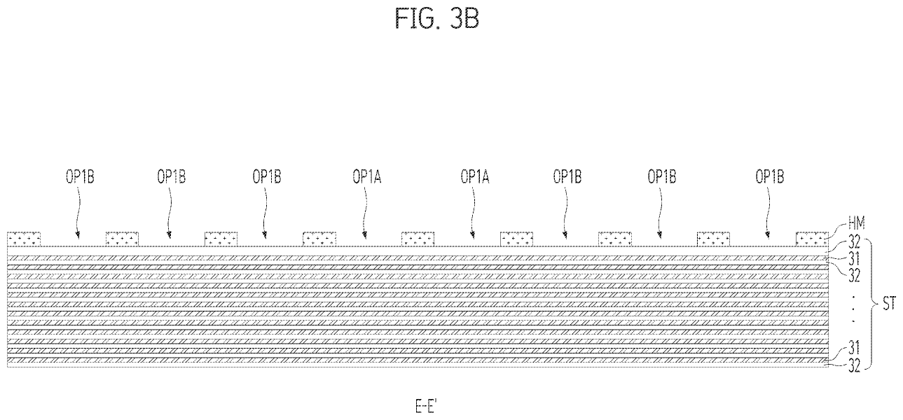

FIGS. 3A, 4A, 5A, 6A, and 7A and FIGS. 3B, 4B, 5B, 6B, and 7B are diagrams for describing a manufacturing method of a semiconductor device in accordance with an embodiment. FIGS. 3A, 4A, 5A, 6A, and 7A are plan views, and FIGS. 3B, 4B, 5B, 6B, and 7B are cross-sectional views taken along lines E-E′ of FIGS. 3A, 4A, 5A, 6A, and 7A, respectively. Hereinafter, the content overlapping with the previously described content may be omitted.

Referring to FIGS. 3A and 3B, a stack ST including first material layers 31 and second material layers 32 that are alternately stacked may be formed. Here, the first material layers 31 may each include a material having a high etching selectivity with respect to the second material layers 32. The first material layers 31 may be used to form gate lines. The second material layers 32 may be used to insulate the stacked gate lines from each other. In an embodiment, the first material layers 31 may each include a sacrificial material such as nitride or a conductive material such as polysilicon or metal. The second material layers 32 may each include an insulating material such as oxide, and nitride, or air gap.

The stack ST may include a first contact region CTR1, a second contact region CTR2, and a bridge region BR. The bridge region BR may be located between the first contact region CTR1 and the second contact region CTR2. Here, the first contact region CTR1 may belong to a first memory block MB1, and the second contact region CTR2 may belong to a second memory block MB2.

Subsequently, a hard mask pattern HM may be formed on the stack ST. The hard mask pattern HM may include first openings OP1 exposing regions where recess staircase structures are to be formed. The first openings OP1 may be located in the first contact region CTR1 and/or the second contact region CTR2. The first openings OP1 may have the same shape or different shapes from each other. For example, a first opening OP1A may have a ladder shape, and a first opening OP1B may have a line shape in which it extends in the second direction II. The hard mask pattern HM may include nitride.

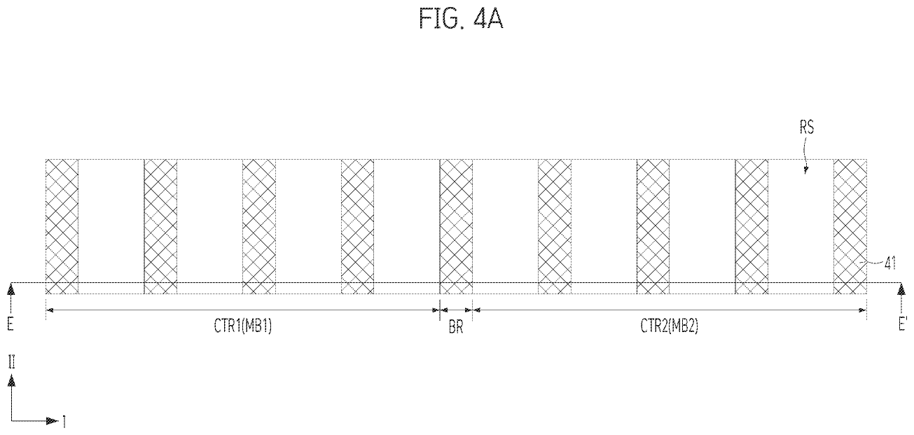

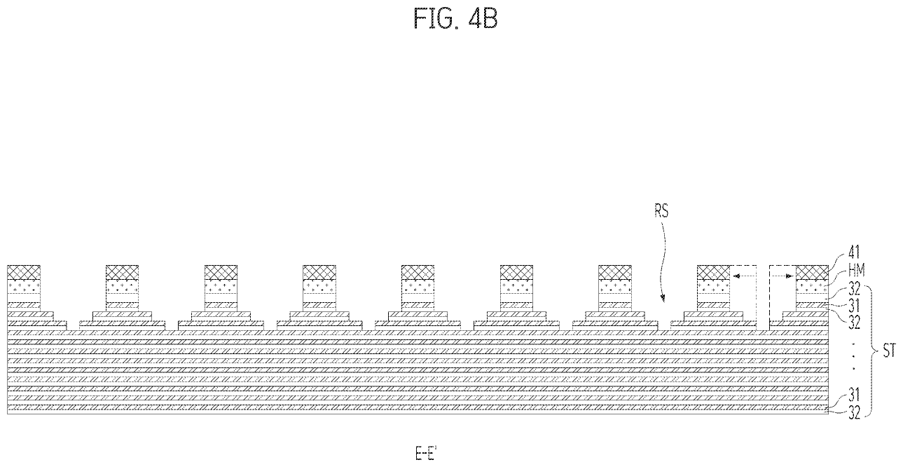

Referring to FIGS. 4A and 4B, a first mask pattern 41 may be formed on the hard mask pattern HM and the stack ST. The first mask pattern 41 may expose at least portions of the regions where the recess staircase structures are to be formed. Subsequently, the recess staircase structures RS may be formed by patterning the stack ST in a staircase shape using the first mask pattern 41 as an etching barrier. In an embodiment, a process of reducing the first mask pattern 41 and etching the stack ST may be repeatedly performed. Through this, the stack ST exposed by the first openings OP1 may be etched to form the recess staircase structures RS. Subsequently, the first mask pattern 41 may be removed.

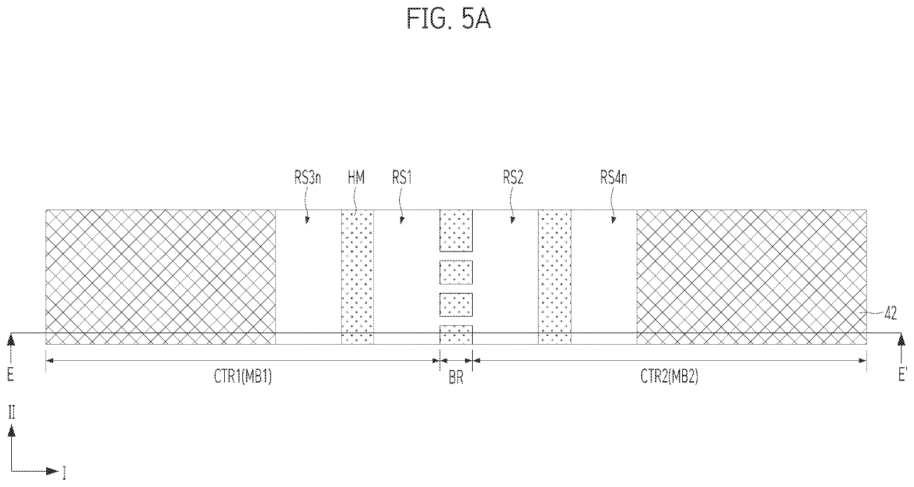

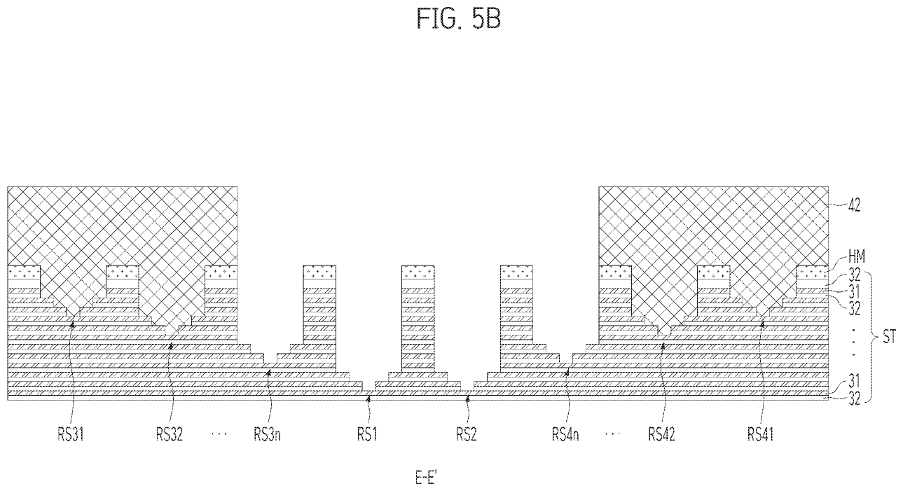

Referring to FIGS. 5A and 5B, a second mask pattern 42 may be formed on the stack ST and the hard mask pattern HM. The second mask pattern 42 may expose at least one of the recess staircase structures RS. Subsequently, the exposed recess staircase structures RS may be extended into the stack ST by using the second mask pattern 42 as an etching barrier. Subsequently, the second mask pattern 42 may be removed. The process of forming the second mask pattern 42 and etching the stack ST may be repeatedly performed for extending the recess staircase structures RS into the stack ST, and forming first to fourth recess staircase structures RS1, RS2, RS31 to RS3n, and RS41 to RS4n having different depths.

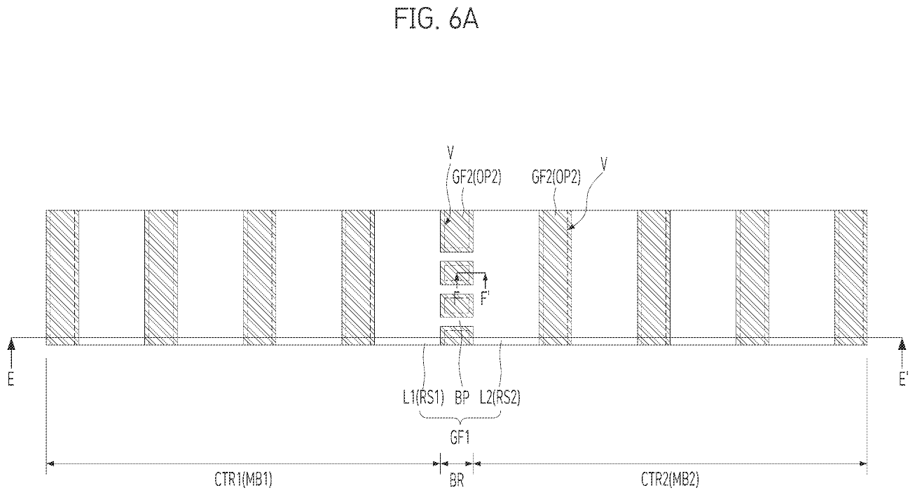

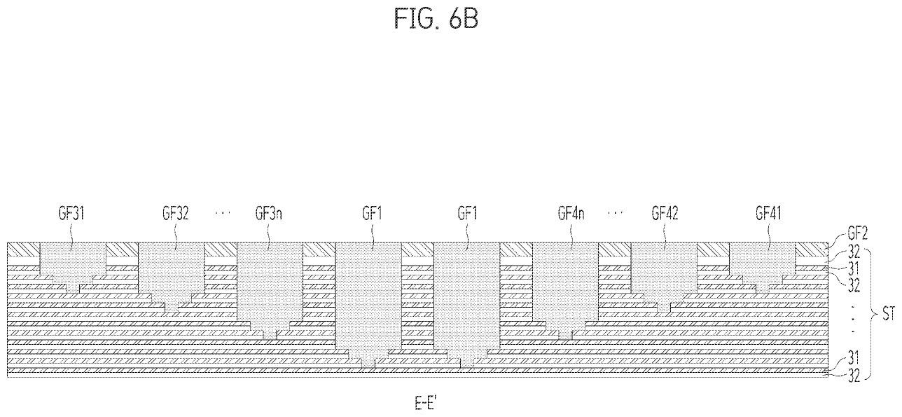

Referring to FIGS. 6A and 6B, gap-fill insulating layers GF1, GF31 to GF3n, and GF41 to GF4n may be formed within the first to fourth recess staircase structures RS1, RS2, RS31 to RS3n, and RS41 to RS4n. In an embodiment, an insulating layer may be formed to fill the first to fourth recess staircase structures RS1, RS2, RS31 to RS3n, and RS41 to RS4n, and the gap-fill insulating layers GF1, GF31 to GF3n, and GF41 to GF4n may be formed by polishing the insulating layer so as to expose the hard mask pattern HM. Through this, a first gap-fill insulating layer GF1 may be formed within the first and second recess staircase structures RS1 and RS2, third gap-fill insulating layers GF31 to GF3n may be formed within the third recess staircase structures RS31 to RS3n, respectively, and fourth gap-fill insulating layers GF41 to GF4n may be formed within the fourth recess staircase structures RS41 to RS4n, respectively. The first, third, and fourth gap-fill insulating layers GF1, GF31 to GF3n, and GF41 to GF4n may each include an oxide layer.

The first gap-fill insulating layer GF1 may include a first line portion L1 formed within the first recess staircase structure RS1, a second line portion L2 formed within the second recess staircase structure RS2, and a bridge portion BP disposed between the first line portion L1 and the second line portion L2 and connecting the first line portion L1 and the second line portion L2 to each other. In a plan view, the first gap-fill insulating layer GF1 may have a ladder shape. Because the hard mask pattern HM exists in an island shape between the bridge portions BP adjacent to each other in the second direction II, dishing caused on an upper surface of the first gap-fill insulating layer GF1 in a process of polishing the insulating layer may be prevented or reduced.

Subsequently, second openings OP2 may be formed by removing the hard mask pattern HM. Subsequently, second gap-fill insulating layers GF2 may be formed within the second openings OP2, respectively. The second gap-fill insulating layer GF2 may include a void V therein, and the void V may have a shape extending along an edge of the first gap-fill insulating layer GF1. The second gap-fill insulating layer GF2 may include an oxide layer formed by a high-density plasma (HDP) method.

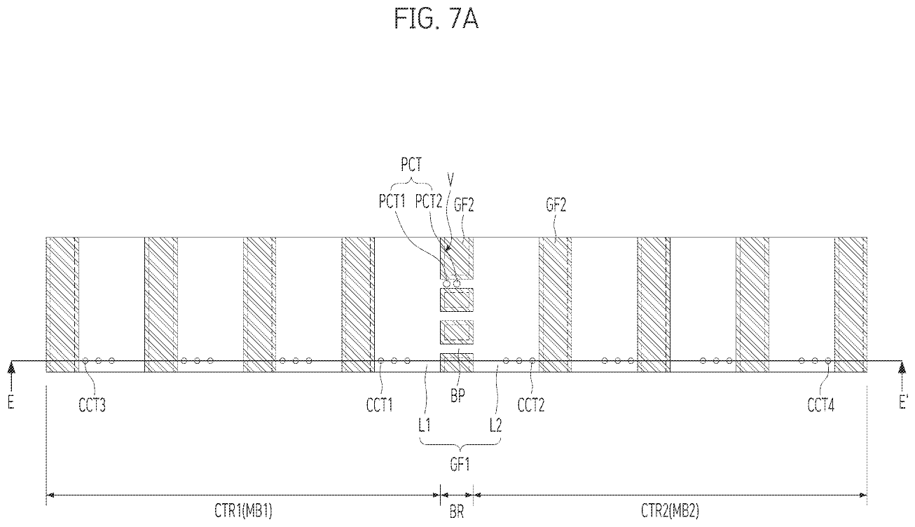

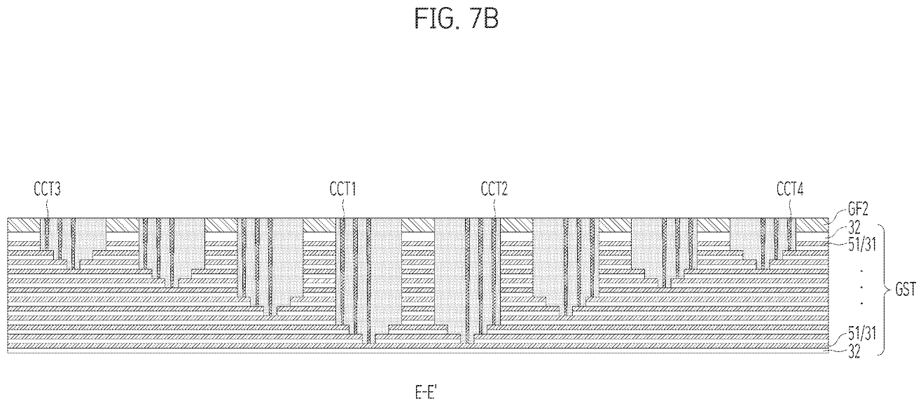

Referring to FIGS. 7A and 7B, the first material layers 31 may be replaced with third material layers 51. In an embodiment, after the first material layers 31 are removed, conductive layers may be formed. Through this, a gate structure GST including the third material layers 51 and the second material layers 32 that are alternately stacked may be formed. During a replacement process, the first material layers 31 may remain in a partial region. In such a case, the partial region of the gate structure GST may include the first material layers 31 and the second material layers 32 that are alternately stacked.

Meanwhile, when the first material layers 31 each include the conductive material, the process of replacing the first material layers 31 with the third material layers 51 may be omitted. In such a case, the first material layers 31 may be used as the third material layers 51, and the stack ST may be used as the gate structure GST.

Subsequently, peripheral contact plugs PCT may be formed. The peripheral contact plugs PCT may be formed between the first line portion L1 and the second line portion L2. The peripheral contact plugs PCT may extend into the gate structure GST through the bridge portion BP of the first gap-fill insulating layer GF1. The peripheral contact plugs PCT may include a first peripheral contact plug PCT1 connected to a gate electrode of a transistor included in a peripheral circuit and a second peripheral contact plug PCT2 connected to a junction of the transistor. The peripheral contact plugs PCT may be spaced apart from the void V.

First cell contact plugs CCT1 extending through the first line portion L1 of the first gap-fill insulating layer GF1 and connected to the first recess staircase structure may be formed. Second cell contact plugs CCT2 extending through the second line portion L2 of the first gap-fill insulating layer GF1 and connected to the second recess staircase structure may be formed. Third cell contact plugs CCT3 extending through the third gap-fill insulating layers GF31 to GF3n and connected to the third recess staircase structures may be formed. Fourth cell contact plugs CCT4 extending through the fourth gap-fill insulating layers GF41 to GF4n and connected to the fourth recess staircase structures may be formed. The first and third cell contact plugs CCT1 and CCT3 may be electrically connected to the third material layers 51, respectively. The second and fourth cell contact plugs CCT2 and CCT4 may be electrically connected to the third material layers 51, respectively.

According to the manufacturing method described above, the first gap-fill insulating layer GF1 having the ladder shape may be formed. The first gap-fill insulating layer GF1 may be formed so that the bridge portion BP is located at a location where the peripheral contact plugs PCT are to be formed, and the peripheral contact plugs PCT may be formed to penetrate through the bridge portion BP. Accordingly, the peripheral contact plugs PCT may be formed at a location spaced apart from the void V, and bridging between the peripheral contact plugs PCT due to the void V may be prevented or reduced.

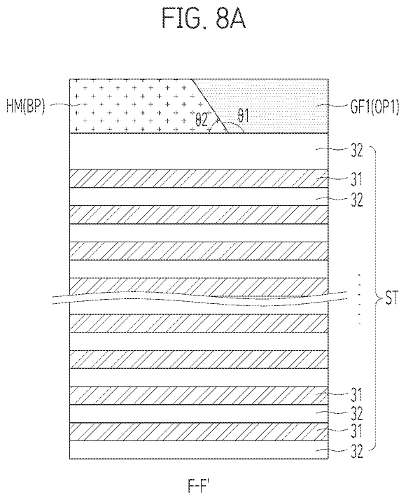

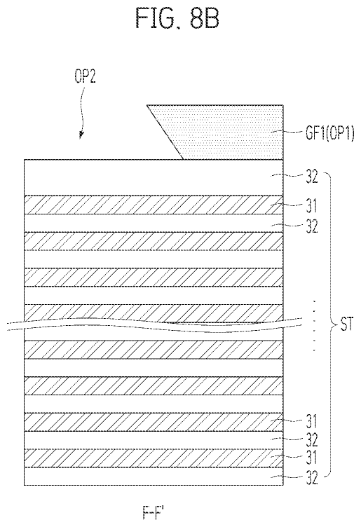

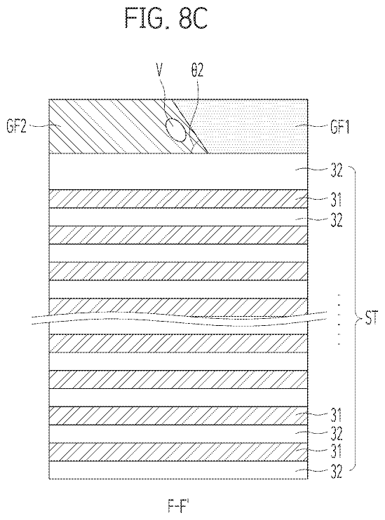

FIGS. 8A to 8C are diagrams for describing a manufacturing method of a semiconductor device in accordance with an embodiment, and are cross-sectional views taken along line F-F′ of FIG. 6A. Hereinafter, the content overlapping with the previously described content may be omitted.

Referring to FIG. 8A, a hard mask pattern HM may be located on a stack ST, and the hard mask pattern HM may include a first opening OP1 having a ladder shape in a plan view. In an embodiment, the hard mask pattern HM may be formed by forming a hard mask material and then etching the hard mask material. The hard mask pattern HM may be formed by etching the hard mask material to have an inclined sidewall. The inclined sidewall of the hard mask pattern HM may have an acute angle θ2 between the inclined sidewall and a bottom surface of the hard mask pattern HM. In an embodiment, the hard mask pattern HM may include an inclined sidewall having an angle θ2 of 70 to 90°.

A first gap-fill insulating layer GF1 may be located within the first opening OP1. In an embodiment, an insulating layer may be formed to fill the first and second recess staircase structures, and the first gap-fill insulating layer GF1 may be formed by polishing the insulating layer. The insulating layer may be deposited along the inclined sidewall of the hard mask pattern HM, and the first gap-fill insulating layer GF1 may include an inclined sidewall of an obtuse angle θ1 between the inclined sidewall and a bottom surface of the first gap-fill insulating layer GF1. In an embodiment, the first gap-fill insulating layer GF1 may include an inclined sidewall having an angle θ1 of 90 to 180°.

Referring to FIG. 8B, a second opening OP2 may be formed by removing the hard mask pattern HM. In an embodiment, the hard mask pattern HM may be selectively removed using a strip process. The second opening OP2 may expose the inclined sidewall of the first gap-fill insulating layer GF1, and may have a cross section with a tapered shape of which a width of a lower portion is greater than a width of an upper portion.

Referring to FIG. 8C, a second gap-fill insulating layer GF2 may be formed within the second opening OP2. The inclined sidewall of the second insulating layer GF2 may have an acute angle θ2 between the inclined sidewall and a bottom surface of the second insulating layer GF2. In an embodiment, the second gap-fill insulating layer GF2 may be formed using a deposition process. An insulating material may be deposited along a profile of an inner surface of the second opening OP2, and a void V may be formed in a deposition process. The void V may be an empty space that is not filled with the insulating material. The void V may extend along an edge of the first gap-fill insulating layer GF1.

According to the manufacturing method described above, the first gap-fill insulating layer GF1 and the second gap-fill insulating layer GF2 may have the inclined sidewalls. Due to the inclined sidewall of the first gap-fill insulating layer GF1, the void V may be formed within the second gap-fill insulating layer GF2. Because the void V is formed along an edge of the bridge portion BP, the peripheral contact plugs PCT may be formed at a location spaced apart from the void V, and bridging between the peripheral contact plugs PCT may be prevented or reduced.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the scope of the present disclosure, and it should be clear to those skilled in the art that these substitutions, modifications, changes, and combinations falls within the scope of the present disclosure.

What is claimed is:

1. A semiconductor device comprising:
a peripheral circuit;
a gate structure disposed on the peripheral circuit, the gate structure including stacked gate lines;
a first recess staircase structure disposed within the gate structure;
a second recess staircase structure disposed within the gate structure adjacent to the first recess staircase structure in a first direction;
a first gap-fill insulating layer including a first line portion formed within the first recess staircase structure, a second line portion formed within the second recess staircase structure, and a bridge portion disposed between the first line portion and the second line portion connecting the first line portion and the second line portion to each other; and
peripheral contact plugs extending into the gate structure through the bridge portion of the first gap-fill insulating layer and connected to the peripheral circuit.

2. The semiconductor device of claim 1, further comprising a second gap-fill insulating layer formed on the gate structure and surrounded by the first line portion, the second line portion, and the bridge portion.

3. The semiconductor device of claim 2, wherein the second gap-fill insulating layer includes a void, the void being spaced apart from the peripheral contact plugs.

4. The semiconductor device of claim 3, wherein the void extends along an edge of the first gap-fill insulating layer.

5. The semiconductor device of claim 1, wherein the first gap-fill insulating layer has a ladder shape.

6. The semiconductor device of claim 1, wherein the first line portion and the second line portion extend in a second direction intersecting the first direction, and the bridge portion extends in the first direction.

7. The semiconductor device of claim 1, wherein the first line portion and the second line portion have bottom surfaces having a staircase shape.

8. The semiconductor device of claim 1, wherein the first line portion and the second line portion extend into the gate structure, and the bridge portion is located on the gate structure.

9. The semiconductor device of claim 1, further comprising:
a first channel structure extending through the gate structure; and
a second channel structure extending through the gate structure.

10. The semiconductor device of claim 9, wherein the first recess staircase structure and the second recess staircase structure are located between the first channel structure and the second channel structure.

11. The semiconductor device of claim 9, further comprising:
a third recess staircase structure located between the first channel structure and the first recess staircase structure; and
a fourth recess staircase structure located between the second channel structure and the second recess staircase structure.

12. The semiconductor device of claim 11, further comprising:
a third gap-fill insulating layer formed within the third recess staircase structure; and
a fourth gap-fill insulating layer formed within the fourth recess staircase structure.

13. The semiconductor device of claim 1, further comprising:
first cell contact plugs extending through the first line portion of the first gap-fill insulating layer and connected to the first recess staircase structure; and
second cell contact plugs extending through the second line portion of the first gap-fill insulating layer and connected to the second recess staircase structure.

14. The semiconductor device of claim 1, wherein the peripheral contact plugs include:
a first peripheral contact plug connected to a gate electrode of a transistor included in the peripheral circuit; and
a second peripheral contact plug connected to a junction of the transistor.

15. The semiconductor device of claim 1, wherein the peripheral contact plugs are spaced apart from an edge of the bridge portion.

16. A semiconductor device comprising:
a peripheral circuit;
a gate structure disposed on the peripheral circuit and including stacked gate lines;
a first recess staircase structure disposed within the gate structure;
a second recess staircase structure disposed within the gate structure;
a first gap-fill insulating layer including a first line portion formed within the first recess staircase structure, a second line portion formed within the second recess staircase structure, and bridge portions connecting the first line portion and the second line portion to each other; and
a second gap-fill insulating layer located between the bridge portions and between the first line portion and the second line portion, wherein the second gap-fill insulating layer includes a void extending along an edge of the first gap-fill insulating layer.

17. The semiconductor device of claim 16, further comprising peripheral contact plugs extending into the gate structure through the bridge portions and connected to the peripheral circuit.

18. The semiconductor device of claim 17, wherein the peripheral contact plugs include:
a first peripheral contact plug connected to a gate electrode of a transistor included in the peripheral circuit; and
a second peripheral contact plug connected to a junction of the transistor.

19. A manufacturing method of a semiconductor device, the manufacturing method comprising:
forming a stack including first material layers and second material layers that are alternately stacked;
forming a hard mask pattern on the stack, the hard mask pattern including a first opening having a ladder shape;
forming a first recess staircase structure by etching the stack exposed by the first opening;
forming a second recess staircase structure by etching the stack exposed by the first opening;
forming a first gap-fill insulating layer including a first line portion formed within the first recess staircase structure, a second line portion formed within the second recess staircase structure, and a bridge portion connecting the first line portion and the second line portion to each other;
forming a second opening by removing the hard mask pattern; and
forming a second gap-fill insulating layer in the second opening, the second gap-fill insulating layer including a void.

20. The manufacturing method of claim 19, wherein the hard mask pattern includes an inclined sidewall having an acute angle between the inclined sidewall and a bottom surface of the mask pattern, and the first gap-fill insulating layer includes an inclined sidewall having an obtuse angle between the inclined sidewall and a bottom surface of the first gap-fill insulating layer.

21. The manufacturing method of claim 19, wherein the first gap-fill insulating layer has an inclined sidewall having an obtuse angle between the inclined sidewall and a bottom surface of the first gap-fill insulating layer, and the second gap-fill insulating layer has an inclined sidewall having an acute angle between the inclined sidewall and a bottom surface of the second gap-fill insulating layer.

22. The manufacturing method of claim 19, wherein in a plan view, the first gap-fill insulating layer has a ladder shape.

23. The manufacturing method of claim 19, wherein the void extends along an edge of the first gap-fill insulating layer.

24. The manufacturing method of claim 19, further comprising:
forming a gate structure by replacing the first material layers with third material layers; and
forming peripheral contact plugs extending into the gate structure through the bridge portion of the first gap-fill insulating layer.

25. The manufacturing method of claim 24, wherein the void is spaced apart from the peripheral contact plug.

26. The manufacturing method of claim 19, further comprising forming first cell contact plugs extending through the first line portion and connected to the first recess staircase structure.

27. The manufacturing method of claim 19, further comprising forming second cell contact plugs extending through the second line portion and connected to the second recess staircase structure.
